(19) United States
(12) Patent Application Publication
(10) Pub. No.: US 2013/0258606 A1
(43) Pub. Date: Oct. 3, 2013

(54) DISPLAY DEVICE WITH REPLACEABLE HOUSING

(71) Applicant: PEGATRON CORPORATION, Taipei (TW)

(72) Inventor: CHAO-YANG HSU, Taipei (TW)

(73) Assignee: PEGATRON CORPORATION, Taipei (TW)

(21) Appl. No.: 13/799,217

(22) Filed: Mar. 13, 2013

(30) Foreign Application Priority Data
Mar. 28, 2012 (TW) 101110755

(51) Int. Cl. H05K 5/02

(52) U.S. Cl. CPC H05K 5/02
USPC 361/728

(57) ABSTRACT

A display device with a replaceable housing, applicable to an electronic product using a flip form, includes: a display panel module, a positioning plate, and an outer cover. The display panel module has a display portion on one side thereof. The positioning plate has a frame piece and a metal plate. The frame piece is disposed at the periphery of the display panel module. The metal plate is fixed at the frame piece to cover the other side of the display panel module. The outer cover is detachably joined with the positioning plate and covers the positioning plate.

### CROSS-REFERENCES TO RELATED APPLICATIONS

This non-provisional application claims priority under 35 U.S.C. §119(a) on Patent Application No. 101110755 filed in Taiwan, R.O.C. on 2012, Mar., 28, the entire contents of which are hereby incorporated by reference.

### BACKGROUND OF THE INVENTION

1. Technical Field

The present invention relates to a display device, and more particularly to a display device with a replaceable housing.

2. Related Art

With the development of technology and under the influences of use habits of customers, current electronic devices such as notebook computers and tablet computers continue to become lighter and smaller. However, only the requirements of light weight and small size are met; the personalization demands of customers are not met. Therefore, users usually put personalized stickers or color pictures on the housings of electronic devices, to demonstrate personal tastes or styles.

Apart from personalized stickers or color pictures, a further replaceable housing structure for easy personalized demonstration appears. In a conventional electronic device with a replaceable housing, a two-layer housing structure is mainly disposed. To replace a housing, a user need only remove the outer housing. However, in such a two-layer housing structure, two housing layers are stacked. Although a user may replace the housing thereof, such a structure significantly increases the thickness of an electronic device, which instead increases the weight and sizes of electronic devices.

### SUMMARY

In view of this, the present invention provides a display device with a replaceable housing, which is applicable to an electronic product using a flip form, and includes: a display panel module, a positioning plate, and an outer cover. The display panel module has a display portion on one side thereof. The positioning plate has a frame piece and a metal plate. The frame piece is disposed at the periphery of the display panel module. The metal plate is fixed at the frame piece to cover the other side of the display panel module. The outer cover is detachably joined with the positioning plate and covers the positioning plate.

The efficacy of the present invention is as follows: The positioning plate, used as an internal structural piece, is capable of enhancing the overall structural strength, and effectively solving the problem of the excessive thickness of a conventional two-layer housing without increasing the thickness. In addition, when the outer cover and the positioning plate are joined, to replace the housing, a user removes the outer cover and places another outer cover to be joined with the positioning plate, which is simple and convenient; also, when an outer cover is being removed, the display panel is protected by the positioning plate, so as to effectively prevent internal electronic components from being damaged during the replacement of housing. Additionally, the positioning plate is made of a metal material, so as to effectively insulate electromagnetic interferences (EMIs).

Detailed features and advantages of the present invention are described in the embodiments below, and their content is adequate for those skilled in the art to understand the technical content of the present invention and to implement the present invention. According to the content disclosed in the specification, the claims, and the drawings, those skilled in the art can easily understand the objects and advantages of the present invention.

### BRIEF DESCRIPTION OF THE DRAWINGS

The present invention will become more fully understood from the detailed description given herein below for illustration only, and thus not limitative of the present invention, wherein:

FIG. 1 is a schematic outside view according to a first embodiment of the present invention;

FIG. 2 is a schematic exploded view according to the first embodiment of the present invention;

FIG. 3 is a partial schematic exploded view according to the first embodiment of the present invention;

FIG. 4 is a partial three-dimensional schematic sectional view according to the first embodiment of the present invention;

FIG. 5 is a partial schematic assembly view according to the first embodiment of the present invention;

FIG. 6 is a partial schematic sectional side view according to the first embodiment of the present invention;

FIG. 7 is a schematic view of the present invention when an outer cover is removed;

FIG. 8 is a schematic outside view according to a second embodiment of the present invention;

FIG. 9 is a partial schematic exploded view according to the second embodiment of the present invention;

FIG. 10 is a partial schematic assembly view according to the second embodiment of the present invention; and

FIG. 11 is a schematic view when an outer cover is removed according to the second embodiment of the present invention.

### DETAILED DESCRIPTION

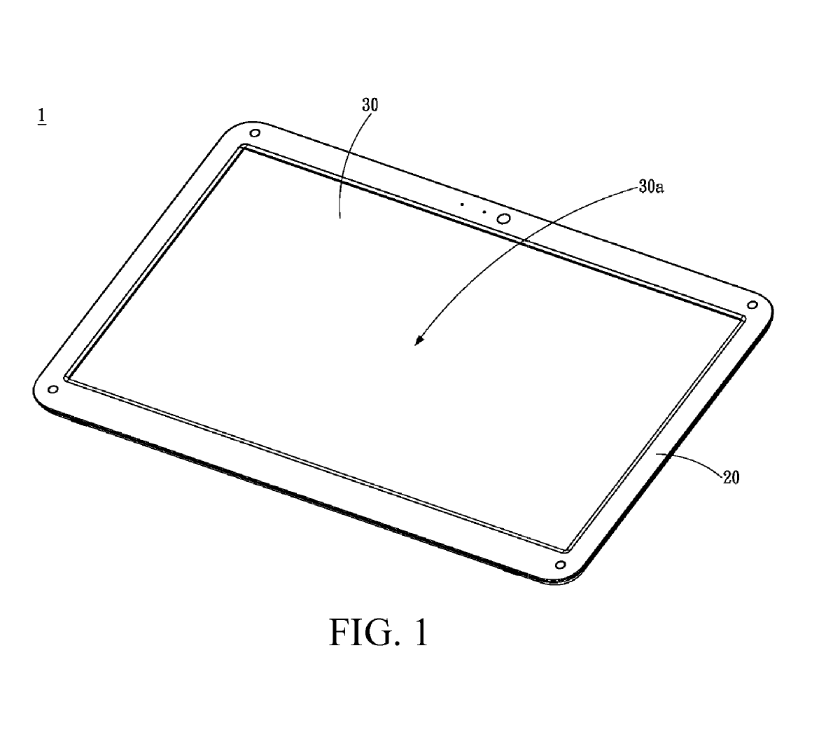

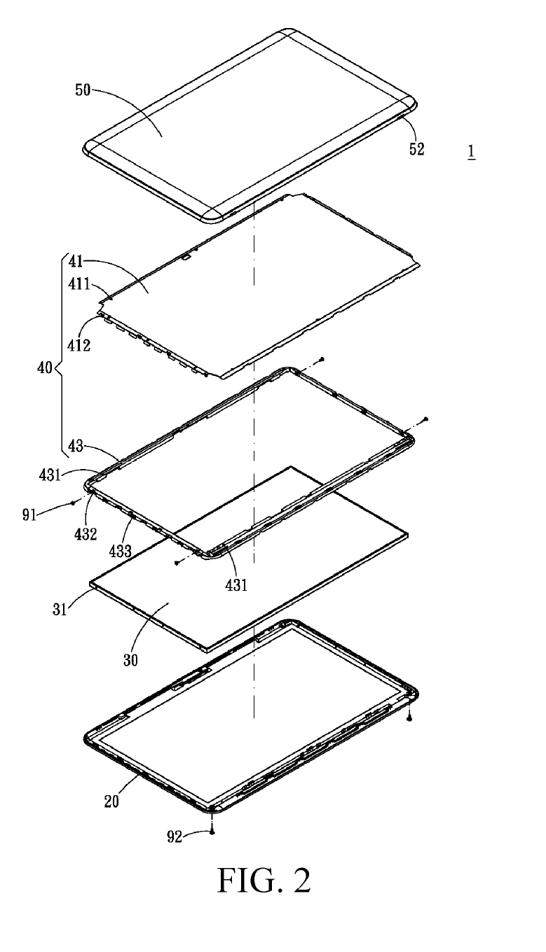

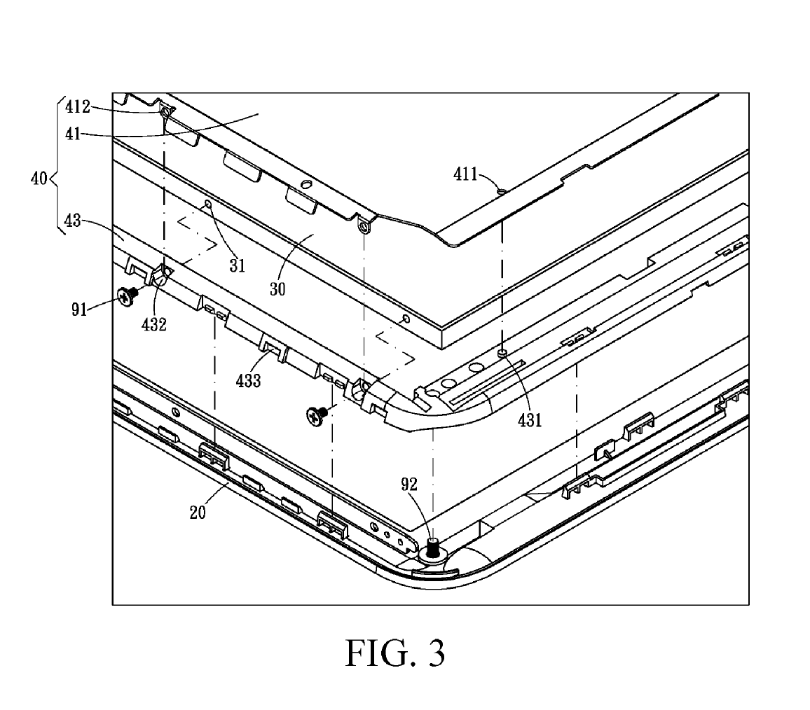

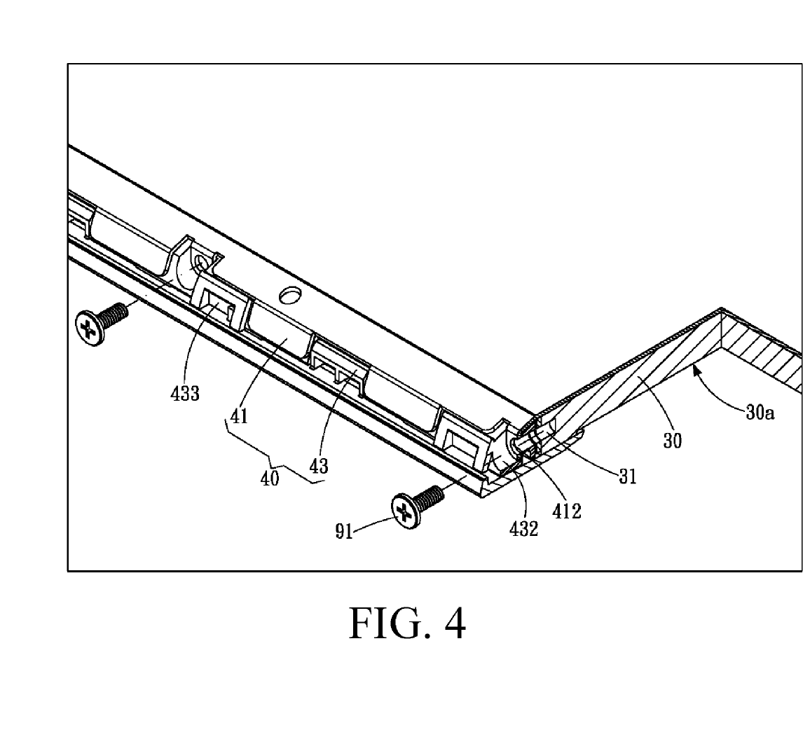

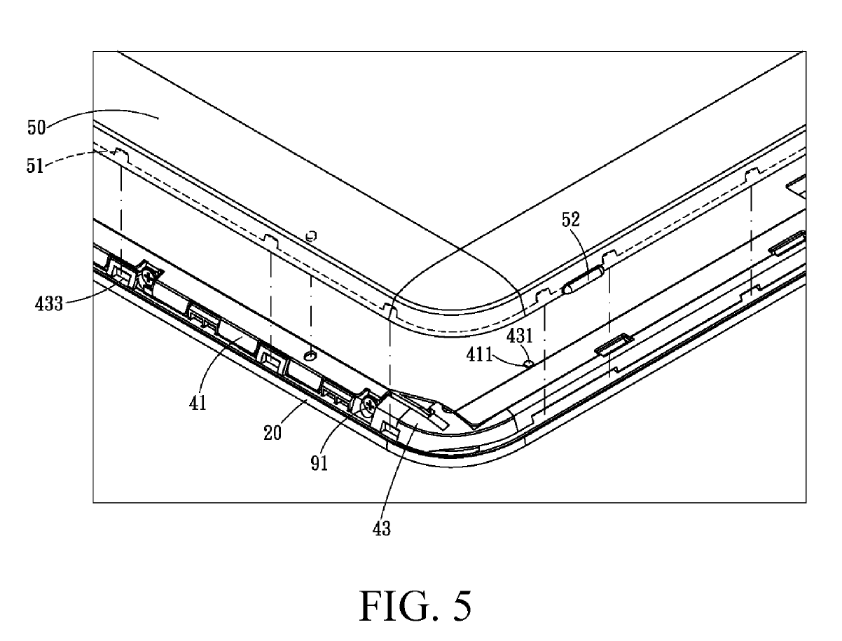

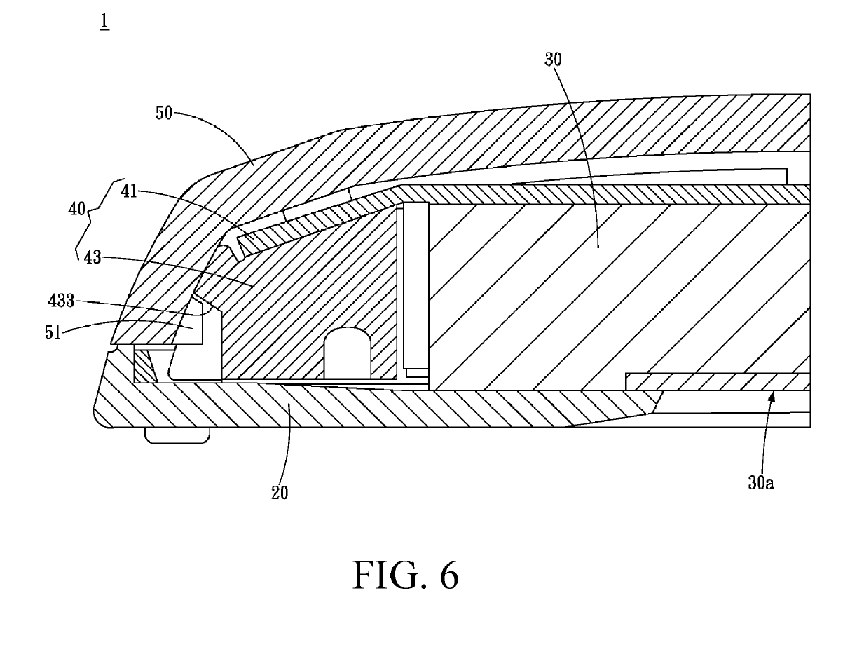

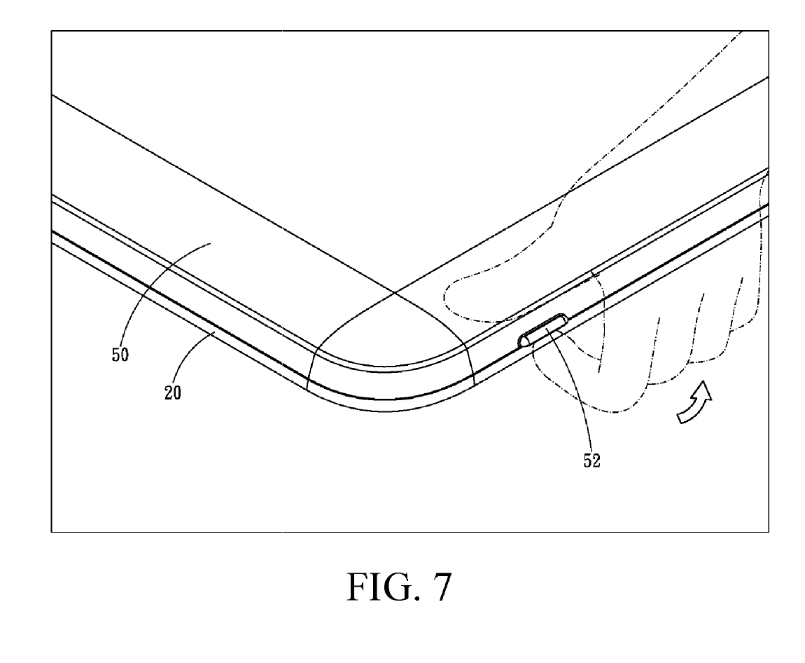

Please refer to FIG. 1, FIG. 2, FIG. 3, FIG. 4, FIG. 5, and FIG. 6, which show a first embodiment of the present invention. FIG. 1 is a schematic outside view of the present invention. FIG. 2 is a schematic exploded view of the present invention. FIG. 3 is a partial schematic exploded view of the present invention. FIG. 4 is a partial three-dimensional schematic sectional view of the present invention. FIG. 5 is a partial schematic assembly view of the present invention. FIG. 6 is a partial schematic sectional side view of the present invention. FIG. 7 is a schematic view of the present invention when an outer cover is removed. A display device with a replaceable housing 1 according to the first embodiment of the present invention includes a display panel module 30, a positioning plate 40, and an outer cover 50.

The display panel module 30 has a display portion 30a on one side, and the other side is a rear side. The positioning plate 40 is disposed at the rear side of the display panel module 30, and covers the rear side of the display panel module 30. Here, the positioning plate 40 is mainly formed of a metal plate 41 and a frame piece 43. The metal plate 41 may be a rectangular metal plate, and is preferably made of aluminum. The frame piece 43 may be made of a plastic material, and is disposed at the periphery of the metal plate 41. The frame piece 43 is disposed at the periphery of the display panel module 30. The metal plate 41 is fixed at the frame piece 43 to cover the rear side of the display panel module 30.

In this embodiment, the metal plate 41 may be used to cover the display panel module 30 to effectively insulate an EMI effect, and the strength of the positioning plate 40 is enhanced by the metal characteristic of the metal plate 41 and the thickness of the positioning plate 40 is reduced, so as to achieve the objective of protecting the display panel module 30. The frame piece 43 is made of a plastic material and can effectively reduce the weight of the positioning plate 40.

Here, the metal plate 41 is disposed with a first joining piece 411. The frame piece 43 is disposed with a second joining piece 431 corresponding to the first joining piece 411. The first joining piece 411 may be a through hole structure, the second joining piece 431 may be a boss structure (as shown in FIG. 3), and the first joining piece 411 and the second joining piece 431 are engaged to position the metal plate 41 and the frame piece 43. The above structures of the first joining piece 411 and the second joining piece 431 are only an example, and the present invention is not limited thereto, and the structures of the two are interchangeable, for example, the first joining piece 411 may be a boss structure, whereas the second joining piece 431 may be a through hole structure.

In addition, the metal plate 41 may be disposed with a positioning piece 412 extending from the periphery thereof. The frame piece 43 is disposed with a positioning portion 432 corresponding to the positioning piece 412. The positioning piece 412 is perpendicular to the body of the metal plate 41, and may be provided with a through hole, so that when the metal plate 41 and the frame piece 43 are joined, the positioning piece 412 is engaged at the positioning portion 432, so as to fix the metal plate 41 and the frame piece 43 by inserting a first screw component 91 through the positioning piece 412 and the positioning portion 432. In addition, the display panel module 30 may be provided with a positioning hole 31 corresponding to the positioning portion 432. When the display panel module 30 is installed on the positioning plate 40, the first screw component 91 may be inserted through the positioning piece 412, the positioning portion 432 and the positioning hole 31, so as to secure the display panel module 30 at the positioning plate 40 (as shown in FIG. 3).

The above manner of joining the metal plate 41 and the frame piece 43 is only an example, and the present invention is not limited thereto; for example, an adhesive may be applied at the periphery of the metal plate 41 and the frame piece 43 is adhered on the metal plate 41 through the adhesive.

In this embodiment, after the display panel module 30 is installed on the positioning plate 40, a front frame piece 20 is assembled at the periphery of the front surface of the display panel module 30 (that is, the side with the display portion 30a), so as to envelop the display panel module 30 between the front frame piece 20 and the positioning plate 40. As shown in FIG. 3, the front frame piece 20 may be screwed at the frame piece 43 of the positioning plate 40 through the second screw component 92.

The outer cover 50 is detachably joined with the positioning plate 40, and the outer cover 50 covers the positioning plate 40. Here, the positioning plate 40 may be disposed with an insertion portion 433 at the periphery of the frame piece 43, and the outer cover 50 is disposed with a hook 51 corresponding to the insertion portion 433 (as shown in FIG. 5). When the outer cover 50 is being assembled, a force is applied on the outer cover 50 to lock the hook 51 at the insertion portion 433, so as to fix the outer cover 50 on the positioning plate 40 and cover the positioning plate 40. In addition, the outer cover 50 may be disposed with a detachment portion 52 at the lateral side thereof (as shown in FIG. 7). When the outer cover 50 is being removed, a user applies a force on the detachment portion 52 to take the hook 51 of the outer cover 50 away from the insertion portion 433 of the frame piece 43 which is therefore no longer locked at the insertion portion 433, so as to remove the outer cover 50 and replace it with another desired outer cover 50 of the user. The desired outer cover 50 is assembled on the positioning plate 40 in the manner above.

It should be specifically noted that when the outer cover 50 is being removed, the positioning plate 40 covers the rear side of the display panel module 30, the metal plate 41 protects the display panel module 30, so that in the process of removing the outer cover 50 or assembling a new outer cover 50, a user no longer needs to worry about damaging the display panel module 30 due to inappropriate application of force or negligence.

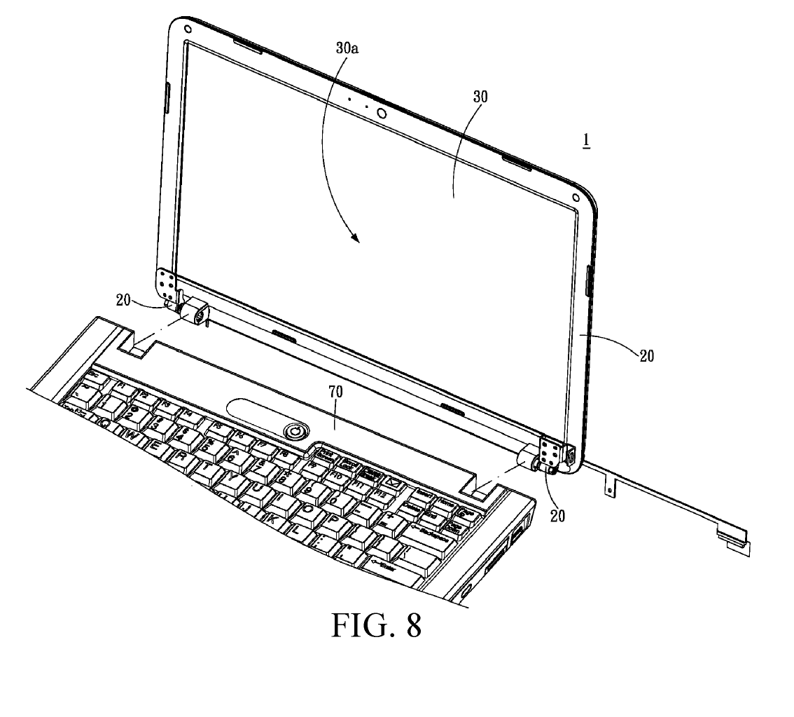

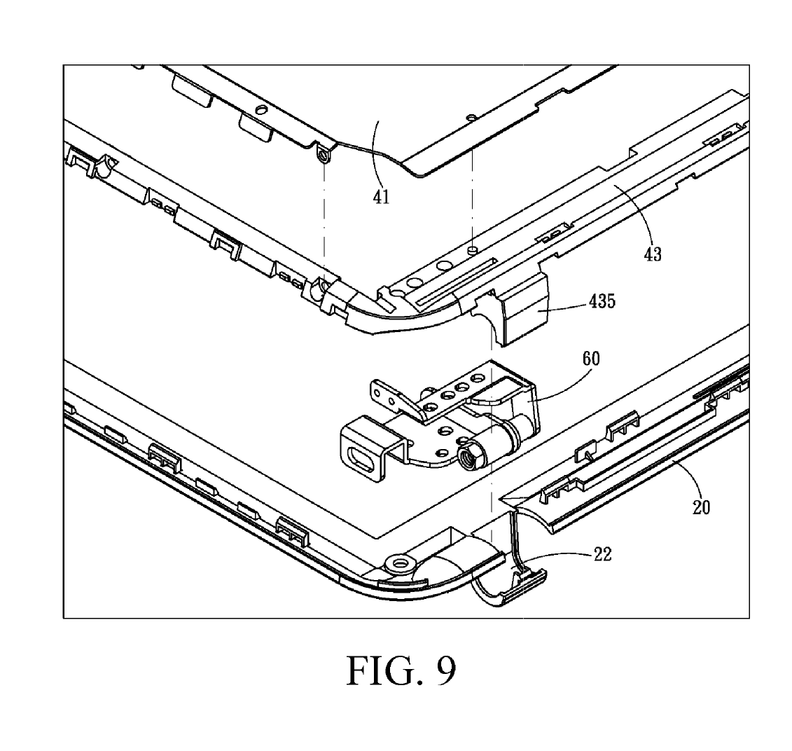

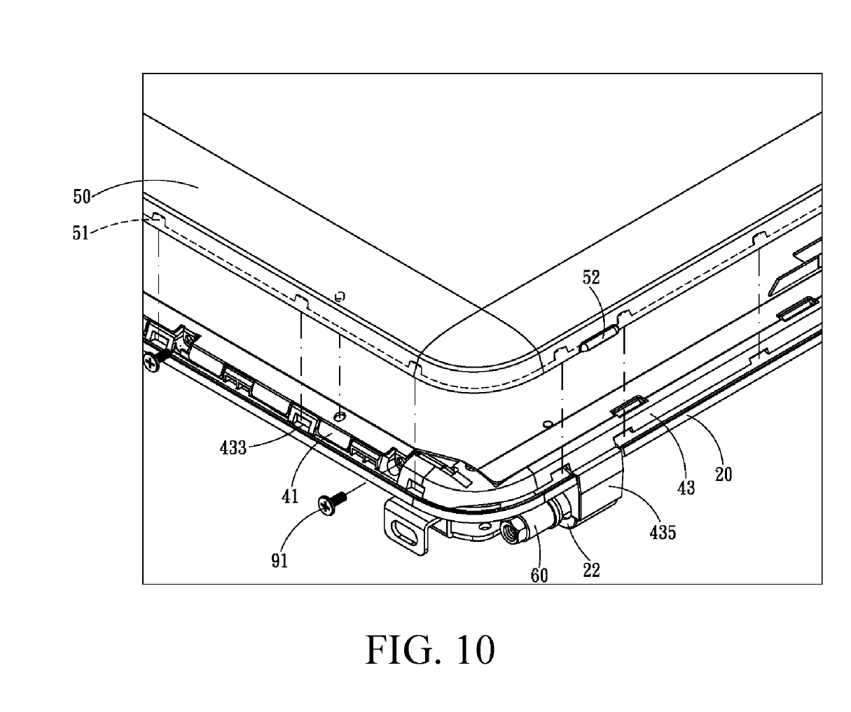

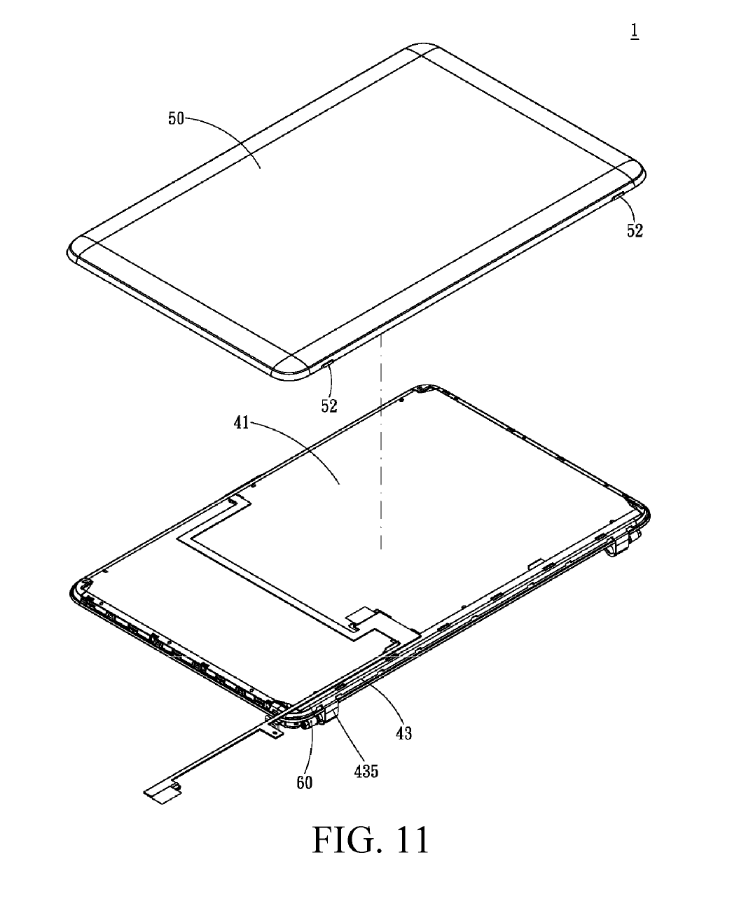

Please refer to FIG. 8, FIG. 9, FIG. 10, and FIG. 11, which show a second embodiment of the present invention. FIG. 8 is a schematic outside view of the present invention. FIG. 9 is a partial schematic exploded view of the present invention. FIG. 10 is a partial schematic assembly view of the present invention. FIG. 11 is a schematic view of the present invention when an outer cover is removed. A display device with a replaceable housing 1 is disclosed in the second embodiment of the present invention. In this embodiment, a notebook computer is taken as an example for an electronic product using a flip form where the present invention is applied; however, the present invention is also applicable to other suitable forms of electronic devices.

In this embodiment, a pivotal connection piece 60 is held between a front frame piece 20 and a frame piece 43 of a positioning plate 40, and the a display device 1 and a main unit 70 of the electronic product using a flip form are pivotally connected through the pivotal connection piece 60. Here, the main unit 70 is provided with a keyboard, and inside the main unit 70 electronic components such as a central processing unit, a memory and a hard disk are provided. The present invention is not limited thereto. By providing the pivotal connection piece 60, the display device 1 is capable of rotating relative to the main unit 70, and when the display device 1 covers the main unit 70, a desired outer cover 50 of a user is exposed.

In addition, the front frame piece 20 is disposed with a first connecting portion 22 at a lateral side thereof. The frame piece 43 is disposed with a second connecting portion 435 at a lateral side thereof. The pivotal connection piece 60 is disposed between the first connecting portion 22 and the second connecting portion 435. The first connecting portion 22 and the second connecting portion 435 may have the structures of being locked to each other. Therefore, the first connecting portion 22 and the second connecting portion 435 are locked to each other to hold the pivotal connection piece 60. The above structures of the first connecting portion 22 and the second connecting portion 435 being locked to each other is merely an example, and the present invention is not limited thereto.

As can be seen from the above, in the present invention, the positioning plate, used as an internal structural piece, is capable of enhancing the overall structural strength, and effectively solving the problem of the excessive thickness of a conventional two-layer housing without increasing the thickness. In addition, when the outer cover is joined with the positioning plate, to replace a housing, a user removes an outer cover and places another outer cover to be joined on the positioning plate, which is simple and convenient; also, when an outer cover is being removed, the positioning plate protects the display panel module, so as to effectively prevent internal electronic components from being damaged during the replacement of housing. Additionally, the positioning plate may be made of a metal material, so as to effectively insulate EMIs.

While the present invention has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A display device with a replaceable housing, applicable to an electronic product using a flip form, comprising:
a display panel module, having a display portion at one side;
a positioning plate, having a frame piece and a metal plate, the frame piece being disposed at the periphery of the display panel module, the metal plate being fixed at the frame piece to cover the other side of the display panel module; and
an outer cover, detachably joined with the positioning plate and covering the positioning plate.

2. The display device with a replaceable housing according to claim 1, wherein the frame piece comprises an insertion portion, the outer cover comprises a hook, and the hook is locked at the insertion portion to fix the outer cover and the positioning plate.

3. The display device with a replaceable housing according to claim 1, wherein the display panel module comprise a front frame piece, the frame piece joined with the front frame piece.

4. The display device with a replaceable housing according to claim 1, wherein the metal plate comprises a first joining piece, the frame piece comprises a second joining piece, and the first joining piece and the second joining piece are engaged to positioning the metal plate and the frame piece.

5. The display device with a replaceable housing according to claim 1, further comprising a first screw component, the metal plate comprises a positioning piece, the frame piece comprises a positioning portion, the first screw component is inserted through the positioning piece and the positioning portion to fix the metal plate at the frame piece.

6. The display device with a replaceable housing according to claim 5, wherein the first screw component is inserted through the display panel module.

7. The display device with a replaceable housing according to claim 3, further comprising a second screw component, and the front frame piece is joined with the frame piece through the second screw component.

8. The display device with a replaceable housing according to claim 7, wherein a pivotal connection piece is held between the front frame piece and the frame piece, and a main unit of the electronic product using a flip form is pivotally connected through the pivotal connection piece.

9. The display device with a replaceable housing according to claim 8, wherein the front frame piece comprises a first connecting portion, the frame piece comprises a second connecting portion, and the first connecting portion and the second connecting portion are joined and hold the pivotal connection piece.

10. The display device with a replaceable housing according to claim 1, wherein the outer cover comprises a detachment portion, a force is applied on the detachment portion to detach the outer cover from the positioning plate.
